(19) United States
(12) Patent Application Publication
(10) Pub. No.: US 2013/0309806 A1
(43) Pub. Date: Nov. 21, 2013

(54) METHOD FOR MANUFACTURING LIGHT-ABSORBING LAYER AND METHOD FOR MANUFACTURING SOLAR CELL USING THE SAME

(71) Applicant: Electronics and Telecommunications Research Institute, (US)

(72) Inventor: Jeong Dae SUH, Daejeon (KR)

(73) Assignee: Electronics and Telecommunications Research Institute, Daejeon (KR)

(21) Appl. No.: 13/757,696

(22) Filed: Feb. 1, 2013

(30) Foreign Application Priority Data
May 16, 2012 (KR) 10-2012-0051955

(51) Int. Cl. H01L 31/032

(52) U.S. Cl. CPC H01L 31/0324
USPC 438/95

(57) ABSTRACT

Provided are a method for manufacturing a light-absorbing layer with excellent flatness of a surface thereof and high density and a method for manufacturing a solar cell using the same. A single target formed of a metallic compound is provided, and a metallic precursor thin film, which is a single layer, is formed on a substrate using the single target. The light-absorbing layer is formed by performing a selenization process on the metallic precursor thin film.

### CROSS-REFERENCE TO RELATED APPLICATIONS

This U.S. non-provisional patent application claims priority under 35 U.S.C. §119 of Korean Patent Application No. 10-2012-0051955, filed on May 16, 2012 the entire contents of which are hereby incorporated by reference.

### BACKGROUND OF THE INVENTION

The present invention disclosed herein relates to a method for manufacturing solar cells, and more particularly, to a method for manufacturing a light-absorbing layer and a method for manufacturing a solar cell using the same.

Solar cells are semiconductor devices directly converting sunlight into electricity. Solar cell technologies aim at enlarging areas, reducing costs, and improving efficiency to be high.

Thin-film solar cells have shorter periods of collecting energy than those of silicone solar cells and can be formed as thin films and have enlarged areas. Accordingly, it is expected that thin-film solar cells may be manufactured at innovatively decreased costs due to development of producing technology. Also, to increase photoelectric transformation efficiency of thin-film solar cells, there have been a lot of studies on developing CIS-based thin-film solar cells using CIS-based thin films having a Cu—In—Ga—Se composite or a Cu—Zn—Sn—Se composite.

Particularly, since Cu—In—Ga—Se (CIGS) thin-film solar cells have higher efficiency than those of amorphous silicon thin film solar cells and are relatively stable such as being without an initial deterioration, there have been developed technologies for commercialization. CIGS thin film solar cells have excellent characteristics to be initially developed as space lightweight high-efficiency solar cells capable of replacing typical single crystal silicon solar cells with an output amount of 20 W/kg. CIGS thin-film solar cells have an output amount per unit weight of 100 W/kg, superior to those of typical silicon or GaAs solar cells such as 20 to 40 W/kg. Currently, CIGS thin-film solar cells provide an efficiency of 20.3% using a co-evaporation method, which reaches an even level with the maximum efficiency of typical polycrystal silicon solar cells.

### SUMMARY OF THE INVENTION

The present invention provides a method for manufacturing a light-absorbing layer having excellent surface-flatness and high density and a method for manufacturing a solar cell using the same.

Embodiments of the present invention provide methods for manufacturing a light-absorbing layer, the methods including providing a single target formed of a metallic compound, forming a metallic precursor thin film, which is a single layer, on a substrate by using the single target, and performing a selenization process on the metallic precursor thin film.

In some embodiments, the metallic compound may be one of CuIn, CuGa, CuInGa, and CuZnSn. The single target formed of the metallic compound may have a composition ratio of one of Cu: In=(1-x): x, Cu: Ga=(1-y): y, Cu: In: Ga=(1-a-b:a:b) and Cu:Zn:Sn=(1-c-d:c:d). In this case, x is a value between 15 to 25%, y is a value between 15 to 25%, a is a value between 45 to 55%, b is a value between 8 to 15%, c is a value between 23 to 28%, and d is a value between 5 to 10%.

In other embodiments, the metallic precursor thin film may be formed of a metallic compound having the same composition as the single target. The operation of forming a metallic precursor thin film may be a sputtering process using the single target.

In still other embodiments, the selenization process may be performed under a condition in which a gap between a top surface of the metallic precursor thin film and a top surface of a selenium evaporation source is 0.5 to 5 mm. Also, the selenization process may be performed under a selenium steam pressure of 10 to 100 Pa.

In other embodiments of the present invention, methods for manufacturing a solar cell include forming a first electrode on a substrate, forming a metallic precursor thin film, which is a single layer, on the first electrode by using a single target formed of a metallic compound, forming a light-absorbing layer by performing a selenization process on the metallic precursor thin film, forming a buffer layer on the light-absorbing layer, forming a window layer on the buffer layer, and forming a second electrode on the window layer.

In some embodiments, the metallic precursor thin film may be formed of a metallic compound having the same composition as the single target.

In other embodiments, the selenization process may be performed under a condition in which a gap between a top surface of the metallic precursor thin film and a top surface of a selenium evaporation source is 0.5 to 5 mm. Also, the selenization process may be performed under a selenium steam pressure of 10 to 100 Pa.

In still other embodiments, the method for manufacturing a solar cell may further include forming a reflection-preventing layer between the window layer and the second electrode.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a flowchart illustrating a method for manufacturing a light-absorbing layer according to an embodiment of the present inventive concept;

FIG. 2 is a concept view illustrating a part of a selenization process according to an embodiment of the present inventive concept;

FIGS. 3A to 3C are scanning electron microscope images of CIS-based light-absorbing layers obtained according to different pressure conditions of selenization processes;

FIG. 4 is a graph of X-ray defraction (XRD) analyzation for the CIS-based light-absorbing layer according to embodiments of the present inventive concept;

FIGS. 5 to 11 are cross-sectional views illustrating a method for manufacturing a thin-film solar cell according to an embodiment of the present inventive concept; and

FIG. 12 is a cross-sectional view illustrating a method for manufacturing a thin-film solar cell according to another embodiment of the present inventive concept.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the drawings, it will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

Embodiments will be described with reference to preferable cross-sectional views and/or top views. In the drawings, the dimensions of layers and regions are exaggerated for clarity of illustration. Accordingly, the regions have schematic characteristics and shapes of the regions are illustratively shown in the drawings to provide certain forms of the regions of a device but not limited thereto. Though there are used terms such as first, second, and third to describe various elements in embodiments, such the elements should not be limited thereby. Such terms are used only for distinguishing one element from others. Embodiments described here with reference to the drawings include complementary embodiments thereof.

Terms used in the description are just for describing embodiments but not limit the present inventive concept. In the specification, a singular form includes a plural form if there is no particular mention about it in phrases. Comprises and/or comprising used in the specification do not exclude presence or addition of one or more elements in addition to a mentioned element.

Hereinafter, it will be described about an exemplary embodiment of the present invention in conjunction with the accompanying drawings.

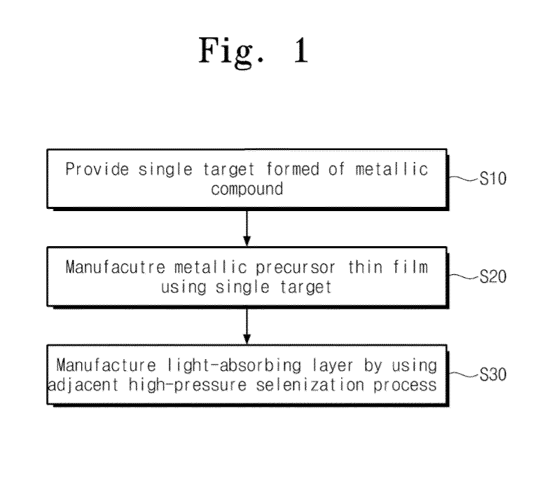

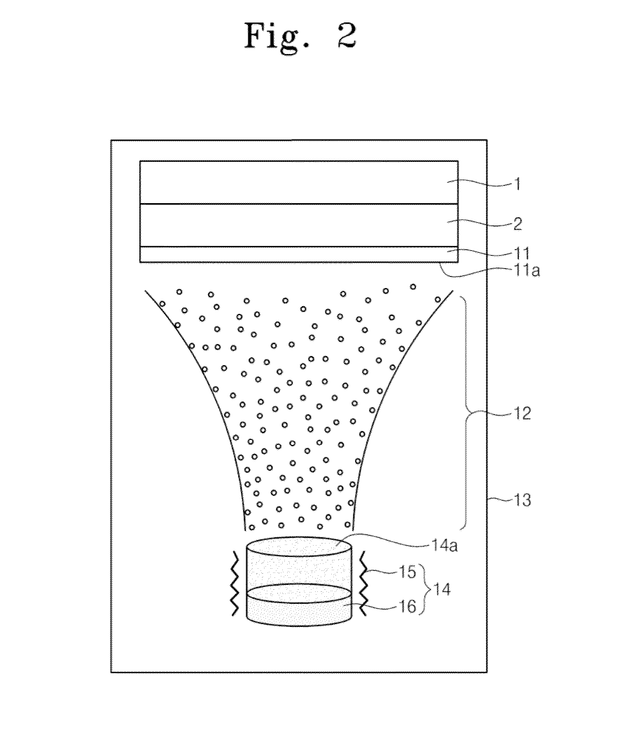

FIG. 1 is a flowchart illustrating a method for manufacturing a light-absorbing layer according to an embodiment of the present inventive concept, and FIG. 2 is a concept view illustrating a part of a selenization process according to an embodiment of the present inventive concept.

Referring to FIGS. 1 and 2, there is provided a single target formed of a metallic compound (S10). The single target may be a target of a sputtering process that will be described after. The metallic compound may be a metal alloy formed by combining metallic elements. The metallic compound may be one of CuIn, CuGA, CuInGA, and CuZnSn. The single target formed of the metallic compound may have a composition ratio of one of Cu:In=(1-x):x, Cu:Ga=(1-y):y, Cu:In:Ga=(1-a-b:a:b) and Cu:Zn:Sn=(1-c-d:c:d), in which x is a value between 15 to 25%, y is a value between 15 to 25%, a is a value between 45 to 55%, c is a value between 8 to 15%, c is a value between 23 to 28%, and d is a value between 5 to 10%.

Next, a metallic precursor thin film 11 is manufactured using the single target (S20). The metallic precursor thin film 11 may be manufactured by a sputtering using the single target. In detail, a substrate 1 is mounted on a chamber for the sputtering using the single target and then the metallic precursor thin film 11 may be formed on the substrate 1. The substrate 1 may be one of glass, a metallic plate, and a polymer. In one embodiment, a first electrode 2 may be provided between the substrate 1 and the metallic precursor thin film 11. As an example, the sputtering process may be performed under a pressure of from about 2 to about 10 mTorr. As an example, the sputtering process may be performed by applying sputtering power of from about 60 to about 150 W. The metallic precursor thin film 11 may be formed of a metallic compound having the same composite as the single target. That is, when using a single target formed of the metallic compound according to the present inventive concept, since a target itself is formed of a metallic compound of a desired composite, it may be easy to control composition of the metallic precursor thin film 11. The metallic precursor thin film 11 manufactured by the sputtering process may have a thickness of about 1 μm.

A light-absorbing layer is manufactured by performing a selenization process on the metallic precursor thin film 11 (S30). The selenization process may be performed in a vacuum furnace or a vacuum chamber.

The metallic precursor thin film 11 formed on the substrate 1 may be mounted on a vacuum chamber 13. There may be provided a selenium evaporation source 14 in the vacuum chamber 13. The selenium evaporation source 14 may include a selenium solid molten liquid 16 and a heater 15 heating the selenium solid molten liquid 16.

The metallic precursor thin film 11 may be arranged adjacent to the selenium evaporation source 14 in a direction to allow a top surface 11a thereof to face a top surface 14a of the selenium evaporation source 14. As an example, a gap between the top surface 11 a of the metallic precursor thin film 11 and the top surface 14a of the selenium evaporation source 14 may be about 0.5 to about 5 mm.

First, selenium elements may be evaporated by heating the selenium evaporation source 14, thereby generating a selenium evaporation gas 12. The selenium evaporation source 14 may be heated at a temperature of about 200 to about 250° C. Comparing with a typical selenization process, since the metallic precursor thin film 11 and the selenium evaporation source 14 are arranged to be adjacent to each other, most the selenium evaporation gas 12 may exist between the metallic precursor thin film 11 and the selenium evaporation source 14. Accordingly, in the selenization process according to the present inventive concept, an amount of the selenium evaporation gas reacting with the metallic precursor thin film 11 may be greater than that of the typical selenization process. As described above, the selenization process according to the present inventive concept may be performed under a higher-pressure condition than that of the typical selenization process. As an example, the selenization process may be performed under a selenium steam pressure of about 10 to about 100 Pa.

After the selenium evaporation gas 12 is generated inside the vacuum chamber 13, the substrate 1 may be heat-treated at a temperature of about 300 to about 650° C. for about 30 to about 60 minutes. Heat-treating the substrate 1, the selenium evaporation gas 12 and the metallic precursor thin film 11 may react with each other. With this, the metallic precursor thin film 11 and the selenium evaporation gas 12 react with each other, thereby manufacturing a selenized light-absorbing layer.

The selenization process may be performed by sequentially heating the outside of the vacuum chamber 13 at a temperature of about 300 to about 650° C. in addition to a method for sequentially heating the selenium evaporation source 14 and the substrate 1 as described above. In other words, by heating the outside of the vacuum chamber 13, the substrate 1 and the selenium evaporation source 14 are heated at the same time, thereby manufacturing the light-absorbing layer.

As an example, the light-absorbing layer manufactured by the selenization process may have a thickness of one of about 500 nm to about 3 μm and about 1 to about 2 μm.

The light-absorbing layer may have a composition of one of Cu—In—Ga—Se and Cu—Zn—Sn—Se. The light-absorbing layer may have a composition ratio of one of Cu:In₍₁₋ₑ₎:Ga₍ₑ₎:Se_{(f)} and Cu₂:Zn:Sn:Se₄, in which e is a numerical value within a range of 0 to 1, f is a numerical value within a range of 1 to 3.

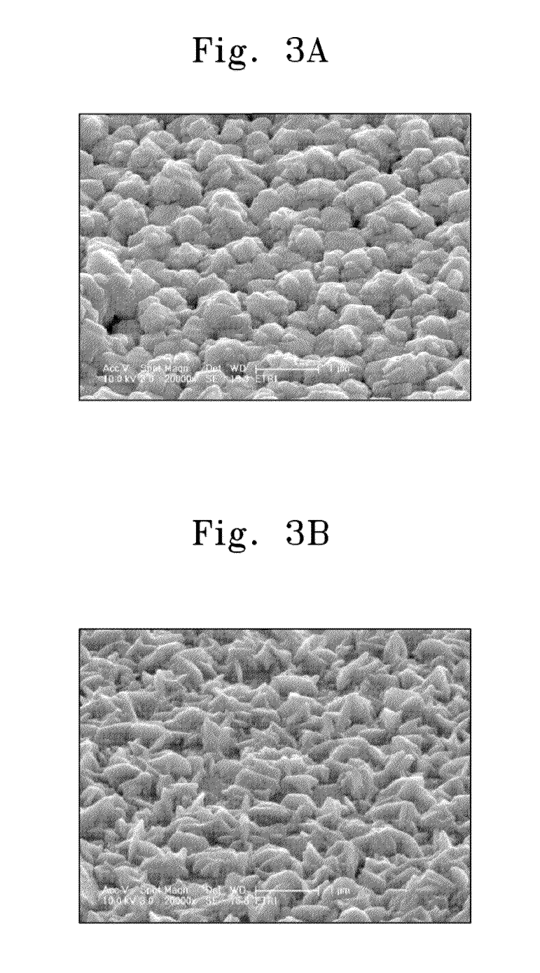

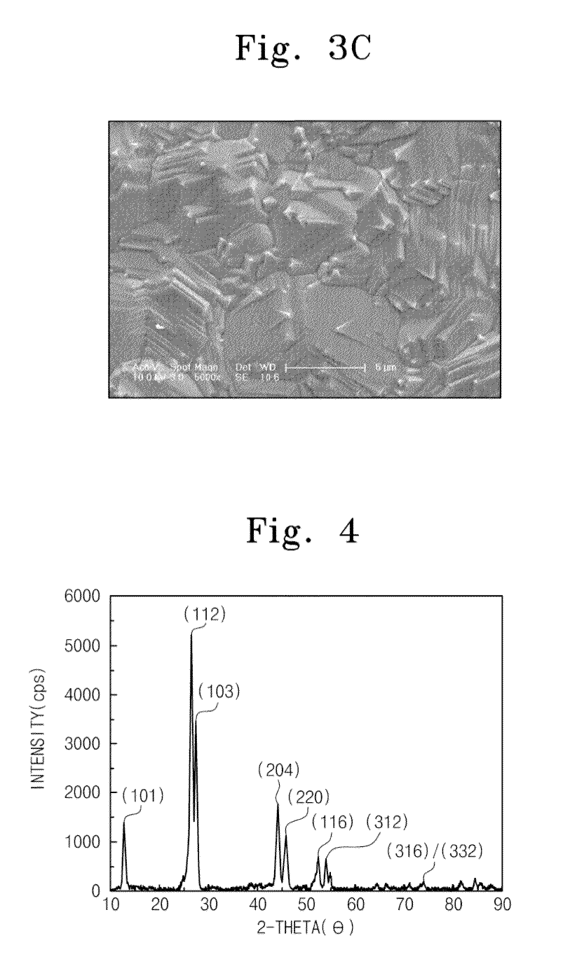

FIGS. 3A to 3C are scanning electron microscope images of CIS-based light-absorbing layers obtained according to different pressure conditions of selenization processes.

FIGS. 3A and 3B illustrate surfaces of CIS-based light-absorbing layers manufactured by a typical low-pressure selenization process after manufacturing a metallic precursor thin film using a single target formed of a metallic compound. The typical low-pressure selenization process may be performed under a selenium steam pressure of about 0.01 to about 1 Pa. Referring to FIG. 3A, it may be understood that crystal grains do not grow densely and there are present a lot of blow holes. Referring to FIG. 3B, it may be understood that the surface of the light-absorbing layer is coarse and uneven.

FIG. 3C illustrates a surface of a CIS-based light-absorbing layer manufactured by the high-pressure selenization process according to the present inventive concept after manufacturing a metallic precursor thin film using a single target formed of a metallic compound. The high-pressure selenization process according to the present inventive concept may be performed under a selenium steam pressure of about 10 to about 100 Pa. Referring to FIG. 3C, it may be understood that there may be manufactured a light-absorbing layer with excellent flatness of a surface thereof and high density in which grains densely grow.

FIG. 4 is a graph of X-ray defraction (XRD) analyzation for the CIS-based light-absorbing layer according to embodiments of the present inventive concept. Referring to FIG. 4, it may be understood that the light-absorbing layer according to an embodiment of the present inventive concept has grown as a CIS-based chalcopyrite crystal structure.

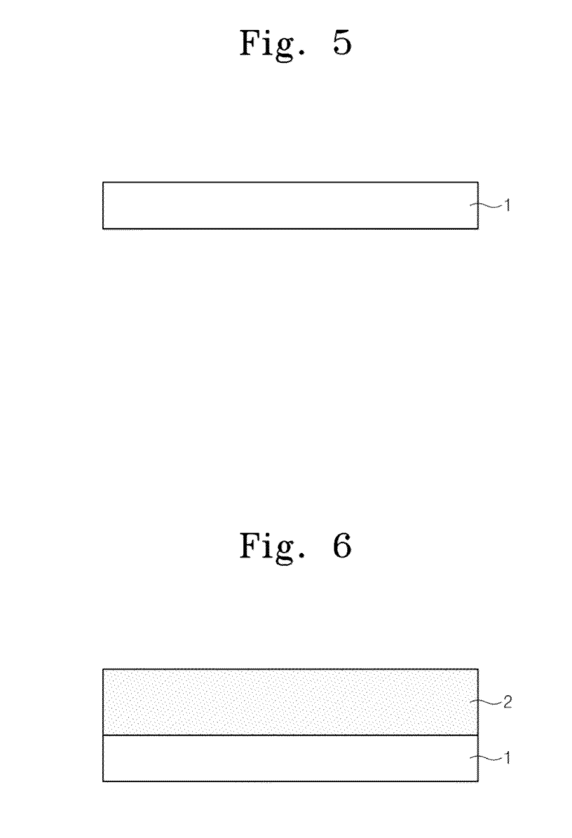

FIGS. 5 to 11 are cross-sectional views illustrating a method for manufacturing a thin-film solar cell according to an embodiment of the present inventive concept.

Referring to FIG. 5, there may be provided the substrate 1. The substrate 1 may be one of glass, a metallic plate, and a polymer. As an example, the substrate 1 may be one of a soda ash glass substrate, a stainless steel substrate, and a polymide polymer substrate. The substrate 1 may be cleaned using deionized water and a cleansing solution. The cleansing solution may be one of acetone and ethanol. After that, the substrate 1 may be washed using the deionized water several times and then dried.

Referring to FIG. 6, there may be provided the first electrode 2 on the substrate 1. The first electrode 2 may include molybdenum (Mo). The first electrode 2 may be deposited on the substrate 1 using a sputtering process. The sputtering process may use a direct current and may be performed under an argon atmosphere of about 1 to about 10 mTorr by applying sputtering power of about 30 to about 100 W. The first electrode 2 deposited by the sputtering process may have a thickness of about 1 μm.

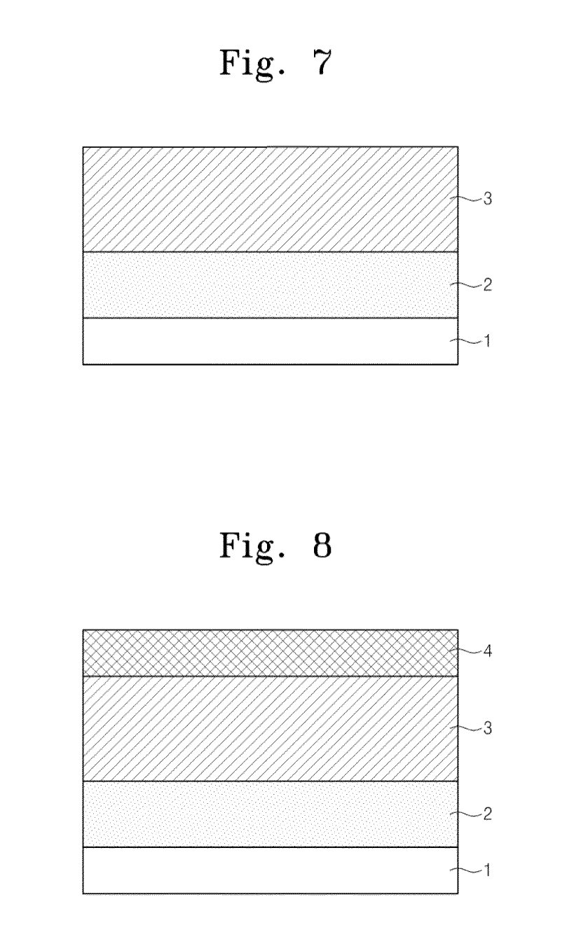

Referring to FIG. 7, there is provided a light-absorbing layer 3 on the first electrode 2. The light-absorbing layer 3 may be manufactured using the method for manufacturing a light-absorbing layer according to the present inventive concept described with reference to FIGS. 1 and 2.

First, there may be provided a single target formed of a metallic compound. In a sputtering chamber using the single target, the substrate 1 where the first electrode 2 is provided, described with reference to FIG. 6, may be mounted thereon. A metallic precursor thin film may be manufactured on the first electrode 2 by the sputtering process. The light-absorbing layer 3 may be manufactured by performing a selenization process on the metallic precursor thin film.

The light-absorbing layer 3 may have a thickness of one of about 500 nm to about 3 μm and about 1 to about 2 μm.

Referring to FIG. 8, there is provided a buffer layer 4 on the light-absorbing layer 3. The buffer layer 4 may be a cadmium sulfide CdS thin film. The buffer layer 4 may be formed by a chemical bath evaporation process. The light-absorbing layer 3 of FIG. 7 is dipped into a solution obtained by mixing cadmium sulfate CdSO₄, ammonium hydroxide NH₄OH, ammonium chloride NH₄Cl, thiourea CS(NH₂)₂, and deionized water, thereby evaporating the cadmium sulfide CdS buffer layer thereon. A temperature of the mixture solution may be about 70° C. The buffer layer 4 may have a thickness of about 50 nm.

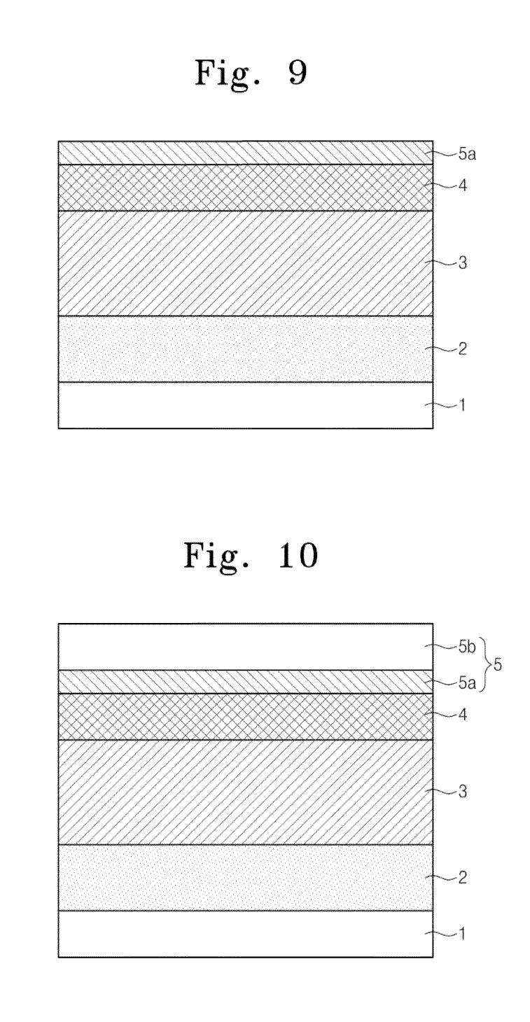

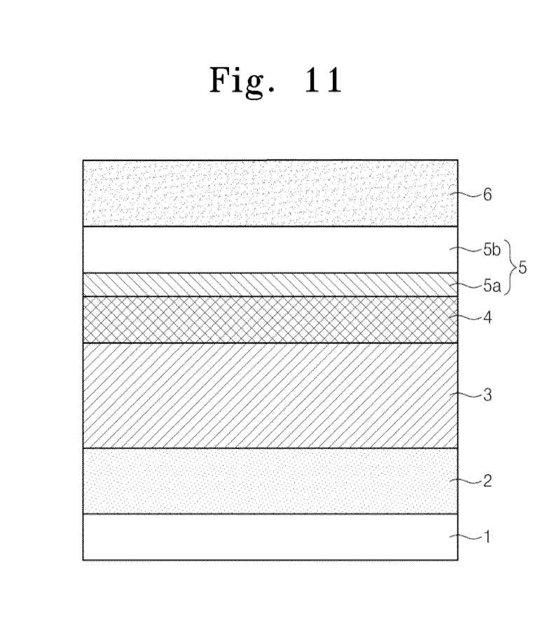

Referring to FIGS. 9 and 10, there may be provided window layers 5 on the buffer layer 4. The window layers 5 may include zinc oxide ZnO. The window layers 5 may be deposited by an RF sputtering process. First, a first window layer 5a may be evaporated on the buffer layer 4 using a ZnO target. The first window layer 5a may have a thickness of about 50 nm. After that, using a ZnO target doped with aluminum oxide Al₂O₃, a second window layer 5b may be evaporated on the first window layer 5a. The second window layer 5b may have a thickness of about 500 nm. The sputtering process forming the window layers 5 may be performed under an argon atmosphere of about 1 to about 10 mTorr by applying sputtering power of about 30 to about 100 W.

Referring to FIG. 11, there may be provided a second electrode 6 on the window layers 5. The second electrode 6 may include aluminum Al. The second electrode 6 may be deposited by a sputtering process.

The solar cell manufactured using the method described with reference to FIGS. 5 to 11 may include the light-absorbing layer according to the present inventive concept. Accordingly, the solar cell including the light-absorbing layer with excellent flatness of a surface thereof and high density may be easily manufactured.

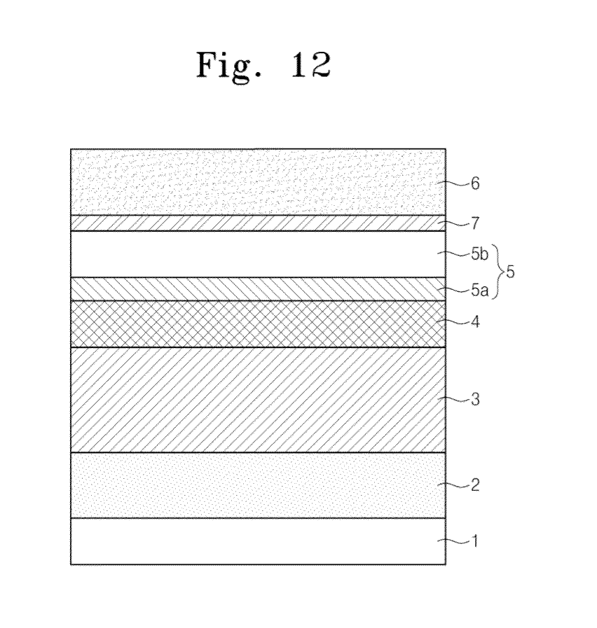

FIG. 12 is a cross-sectional view illustrating a thin-film solar cell according to another embodiment of the present inventive concept. For simplicity of description, there may be omitted a description of a configuration similar to that of the thin-film solar cell according to an embodiment.

Referring to FIG. 12, the thin-film solar cell according to the present embodiment may include the substrate 1, the first electrode 2 on the substrate 1, the light-absorbing layer 3 on the first electrode 2, the buffer layer 4 on the light-absorbing layer 3, the window layers 5 including the first window layer 5a and the second window layer 5b on the buffer layer 4, a reflection-preventing layer 7 on the window layers 5, and the second electrode 6 on the reflection-preventing layer 7.

The reflection-preventing layer 7 may be provided between the window layers 5 and the second electrode 6. The reflection-preventing layer 7 may prevent reflection of sunlight incident to the light-absorbing layer 3. As an example, the reflection-preventing layer 7 may include magnesium fluoride MgF₂.

According to embodiments according to the present inventive concept, there may be easily manufactured a light-absorbing layer with excellent flatness of a surface thereof and high density and a solar cell using the same.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for manufacturing a light-absorbing layer, comprising:
providing a single target formed of a metallic compound;
forming a metallic precursor thin film, which is a single layer, on a substrate by using the single target; and
performing a selenization process on the metallic precursor thin film.

2. The method for claim 1, wherein the metallic compound is one of CuIn, CuGa, CuInGa, and CuZnSn.

3. The method for claim 1, wherein a composition ratio of the metallic compound is one of Cu:In=(1-x):x, Cu:Ga=(1-y):y, Cu:In:Ga=(1-a-b:a:b) and Cu:Zn:Sn=(1-c-d:c:d), in which x is a value between 15 to 25%, y is a value between 15 to 25%, a is a value between 45 to 55%, b is a value between 8 to 15%, c is a value between 23 to 28%, and d is a value between 5 to 10%.

4. The method for claim 1, wherein the metallic precursor thin film is formed of a metallic compound having the same composition as the single target.

5. The method for claim 1, wherein the forming a metallic precursor thin film is a sputtering process using the single target.

6. The method for claim 1, wherein the selenization process is performed under a condition in which a gap between a top surface of the metallic precursor thin film and a top surface of a selenium evaporation source is 0.5 to 5 mm.

7. The method for claim 1, wherein the selenization process is performed under a selenium steam pressure of 10 to 100 Pa.

8. A method for manufacturing a solar cell, comprising:
forming a first electrode on a substrate;
forming a metallic precursor thin film, which is a single layer, on the first electrode by using a single target formed of a metallic compound;
forming a light-absorbing layer by performing a selenization process on the metallic precursor thin film;
forming a buffer layer on the light-absorbing layer;
forming a window layer on the buffer layer; and
forming a second electrode on the window layer.

9. The method for claim 8, wherein the metallic precursor thin film is formed of a metallic compound having the same composition as the single target.

10. The method for claim 8, wherein the selenization process is performed under a condition in which a gap between a top surface of the metallic precursor thin film and a top surface of a selenium evaporation source is 0.5 to 5 mm.

11. The method for claim 8, wherein the selenization process is performed under a selenium steam pressure of 10 to 100 Pa.

12. The method for claim 8, further comprising forming a reflection-preventing layer between the window layer and the second electrode.
